(19) United States
(12) Patent Application Publication
(10) Pub. No.: US 2025/0194192 A1
(43) Pub. Date: Jun. 12, 2025

(54) DIELECTRIC STRUCTURE, SEMICONDUCTOR DEVICE STRUCTURE AND MANUFACTURING METHODS THEREFOR

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/933,780

(22) Filed: Oct. 31, 2024

(30) Foreign Application Priority Data
Dec. 8, 2023 (CN) 202311684792.4

(51) Int. Cl. H01L 29/16; H01L 21/02; H01L 29/66

(52) U.S. Cl. CPC H10D 62/8325; H01L 21/02164; H01L 21/02178; H01L 21/02236; H01L 21/02241; H01L 21/02378; H01L 21/0254; H01L 21/02592; H01L 21/02595; H10D 12/031

(57) ABSTRACT

Disclosed are a dielectric structure, a semiconductor device structure and manufacturing methods therefor. The manufacturing method for the dielectric structure includes growing a single-crystal AlN layer on the SiC substrate, and then simultaneously oxidizing the SiC substrate and the single-crystal AlN layer to form a composite dielectric layer including a SiO₂ layer and a single-crystal AlO_{X} layer. By simultaneously oxidizing the single-crystal AlN layer provided on the surface of the SiC substrate and the SiC substrate, on the one hand, the AlO_{X} layer includes a higher background concentration of nitrogen, so that nitrogen ions diffuse into the SiO₂, thereby improving the interface characteristics of the SiC/SiO₂; and on the other hand, after oxidation of the single-crystal AlN layer, the single-crystal AlO_{X} layer with wide band gap and high-density may be introduced, so that the single-crystal AlO_{X} has good quality and a high-quality interface with SiO₂.

### CROSS-REFERENCE TO RELATED APPLICATIONS

This application claims priority to Chinese Patent Application No. 202311684792.4, filed on Dec. 8, 2023, which is hereby incorporated by reference in its entirety.

### TECHNICAL FIELD

The present disclosure relates to the field of semiconductor technologies, and in particular, to a dielectric structure, a semiconductor device structure and manufacturing methods therefor.

### BACKGROUND

Due to characteristics of high breakdown strength, high electron drift velocity, and high thermal conductivity, SiC material is suitable for preparation of a high-power device. As a typical representative of the third-generation semiconductor, SiC material has excellent physical and chemical properties and is an ideal material for manufacturing a device with characteristics of high-temperature-resistance, high-power, high-frequency, and high-irradiation-resistance. Although SiC Power MOSFET (Metal-Oxide-Semiconductor Field Effect Transistor) has been commercialized, research on gate dielectrics of the SiC Power MOSFET is still of great significance. The gate dielectric is critical in a SiC MOS device because the gate dielectric is required to maintain a high electric field intensity and a low gate leakage current

### SUMMARY

In view of this, embodiments of the present disclosure provide a dielectric structure, a semiconductor device structure, and manufacturing methods therefor, so as to improve quality of a gate dielectric layer in a SiC MOS device.

According to an aspect of the present disclosure, an embodiment of the present disclosure provides a manufacturing method for a dielectric structure. The method includes: providing a SiC substrate; growing a single-crystal AlN layer on the SiC substrate; and simultaneously oxidizing the SiC substrate and the single-crystal AlN layer through a thermal oxidation process to form a composite dielectric layer on the SiC substrate, where the composite dielectric layer includes a SiO₂ layer and a single-crystal AlO_{X} layer stacked sequentially along a direction facing away from the SiC substrate.

According to another aspect of the present disclosure, an embodiment of the present disclosure provides a manufacturing method for a semiconductor device structure. The method includes any one of the manufacturing methods for the dielectric structure mentioned above. Before the growing a single-crystal AlN layer on the SiC substrate, the step of providing a SiC substrate includes: providing a SiC substrate of a first conductivity type; forming a well region of a second conductivity type at two ends of an upper surface of the SiC substrate; forming a source region of the first conductivity type in the upper surface of the well region; and forming a heavily doped drain region of the first conductivity type in a lower surface of the SiC substrate. And after the step of simultaneously oxidizing the SiC substrate and the single-crystal AlN layer through a thermal oxidation process to form a composite dielectric layer on the SiC substrate, where the composite dielectric layer includes a SiO₂ layer and a single-crystal AlO_{X} layer stacked sequentially along a direction facing away from the SiC substrate, the method further includes: performing etching to the composite dielectric layer in a non-gate region to expose the source region; and disposing a source electrode in the source region, disposing a drain electrode in the drain region, and disposing a gate electrode on the composite dielectric layer.

According to still another aspect of the present disclosure, an embodiment of the present disclosure provides a manufacturing method for a semiconductor device structure. The method includes any one of the manufacturing methods for the dielectric structure mentioned above. Before the growing a single-crystal AlN layer on the SiC substrate, the step of providing a SiC substrate includes: providing a SiC substrate of a first conductivity type; and performing etching to an upper surface of the SiC substrate to form a trench. And the step of growing a single-crystal AlN layer on the SiC substrate includes: growing the single-crystal AlN layer on a side wall and a bottom of the trench. And after the step of simultaneously oxidizing the SiC substrate and the single-crystal AlN layer through a thermal oxidation process to form a composite dielectric layer on the SiC substrate, where the composite dielectric layer includes a SiO₂ layer and a single-crystal AlO_{X} layer stacked sequentially along a direction facing away from the SiC substrate, the method further includes: forming a well region of a second conductivity type in the upper surface of the SiC substrate; forming a source region of the first conductivity type in the upper surface, closer to the composite dielectric layer, of the well region; forming a heavily doped drain region of the first conductivity type in a lower surface of the SiC substrate; and disposing a gate electrode in a groove of the composite dielectric layer, disposing a source electrode in the source region, and disposing a drain electrode in the drain region.

According to another aspect of the present disclosure, an embodiment of the present disclosure provides a dielectric structure, prepared by any one of the manufacturing methods for the dielectric structure mentioned above, including a SiC substrate and a composite dielectric layer stacked in layers, where the composite dielectric layer includes a SiO₂ layer and a single-crystal AlO_{X} layer stacked sequentially along a direction facing away from the SiC substrate.

According to yet still another aspect of the present disclosure, an embodiment of the present disclosure provides a semiconductor device structure, prepared by any one of the manufacturing methods for the semiconductor device structure mentioned above. The semiconductor device structure includes: a SiC substrate of a first conductivity type; a well region of a second conductivity type located at two ends of an upper surface of the SiC substrate; a source region of the first conductivity type located in the upper surface of the well region, and a source electrode in contact with the source region; a heavily doped drain region of the first conductivity type located in a lower surface of the SiC substrate, and a drain electrode in contact with the drain region; and a composite dielectric layer and a gate electrode located in a gate region of the upper surface of the SiC substrate, where the composite dielectric layer includes a SiO₂ layer and a single-crystal AlO_{X} layer stacked sequentially along a direction facing away from the SiC substrate.

According to yet still another aspect of the present disclosure, an embodiment of the present disclosure provides a semiconductor device structure prepared by any one of the manufacturing methods for the semiconductor device structure mentioned above. The semiconductor device structure includes: a SiC substrate of a first conductivity type, where an upper surface of the SiC substrate is provided with a trench; a well region of a second conductivity type located in the upper surface of the SiC substrate; a source region of the first conductivity type located in the upper surface, closer to the trench, of the well region, and a source electrode in contact with the source region; a heavily doped drain region of the first conductivity type located in a lower surface of the SiC substrate, and a drain electrode in contact with the drain region; and a composite dielectric layer located on a side wall and a bottom of the trench, and a gate electrode located in a groove of the composite dielectric layer, where the composite dielectric layer includes a SiO₂ layer and a single-crystal AlO_{X} layer stacked sequentially along a direction facing away from the SiC substrate.

### BRIEF DESCRIPTION OF THE DRAWINGS

FIG. 1 is a flowchart of a manufacturing method for a dielectric structure according to an embodiment of the present disclosure.

FIGS. 2 and 3 are schematic diagrams of intermediate structures corresponding to the process shown in FIG. 1.

FIG. 4 is a schematic structural diagram of a dielectric structure according to an embodiment of the present disclosure.

FIG. 5 is a schematic structural diagram of a dielectric structure before oxidation according to an embodiment of the present disclosure.

FIG. 6 is a schematic structural diagram of a dielectric structure after oxidation according to an embodiment of the present disclosure.

FIG. 7 is a schematic structural diagram of a dielectric structure before oxidation according to an embodiment of the present disclosure.

FIG. 8 is a schematic structural diagram of a dielectric structure after oxidation according to an embodiment of the present disclosure.

FIG. 9 is a flowchart of a manufacturing method for a semiconductor device structure according to an embodiment of the present disclosure.

FIGS. 10 to 16 are schematic diagrams of intermediate structures corresponding to the process shown in FIG. 9.

FIG. 17 is a flowchart of a manufacturing method for a semiconductor device structure according to an embodiment of the present disclosure.

FIGS. 18 to 22 are schematic diagrams of intermediate structures corresponding to the process shown in FIG. 17.

FIG. 23 is a flowchart of a manufacturing method for a semiconductor device structure according to another embodiment of the present disclosure.

FIG. 24 is a flowchart of a manufacturing method for a semiconductor device structure according to still another embodiment of the present disclosure.

FIG. 25 is a flowchart of a manufacturing method for a semiconductor device structure according to yet still another embodiment of the present disclosure.

### DETAILED DESCRIPTION OF THE EMBODIMENTS

Technical solutions in the embodiments of the present disclosure are clearly and completely described below with reference to accompanying drawings in the embodiments of the present disclosure. Obviously, the described embodiments are only a part of embodiments of the present disclosure, not all of them. Based on the embodiments of the present disclosure, all other embodiments obtained by a person of ordinary skill in the art without creative efforts shall fall within protection scope of the present disclosure.

During a manufacture process of a SiC MOS device, a gate dielectric layer with low quality greatly limits performance of the SiC MOS device. For example, when a SiO₂ gate dielectric layer is obtained by means of direct thermal oxidation growth of SiC, an interface between SiC and the SiO₂ gate dielectric layer often inevitably has many interface defects, so that a channel mobility is greatly reduced.

In order to reduce a large number of interface states existing between SiC and SiO₂ grown by a traditional direct thermal oxidation method, improve the channel mobility, and improve forward conduction capability of the device, the present disclosure provides a dielectric structure, a semiconductor device structure, and manufacturing methods therefor. After growing a single-crystal AlN layer on a SiC substrate, the SiC substrate and the single-crystal AlN layer are simultaneously oxidized to form a composite dielectric layer including a SiO₂ layer and a single-crystal AlO_{X} layer. According to the present disclosure, by simultaneously oxidizing the single-crystal AlN layer provided on the surface of the SiC substrate and the SiC substrate, on the one hand, the single-crystal AlO_{X} layer formed by the oxidation of the single-crystal AlN layer includes a higher background concentration of nitrogen, so that nitrogen ions diffuse into the SiO₂, thereby improving interface characteristics of SiC/SiO₂, reducing interface states with a high density at the interface of SiC/SiO₂, and improving the quality of the SiO₂ layer; on the other hand, after oxidation of the single-crystal AlN layer, the single-crystal AlO_{X} layer with wide band gap and high-density may be introduced. As the single-crystal AlO_{X} has good quality and has a high-quality interface with SiO₂, the quality of the composite dielectric layer may be further improved.

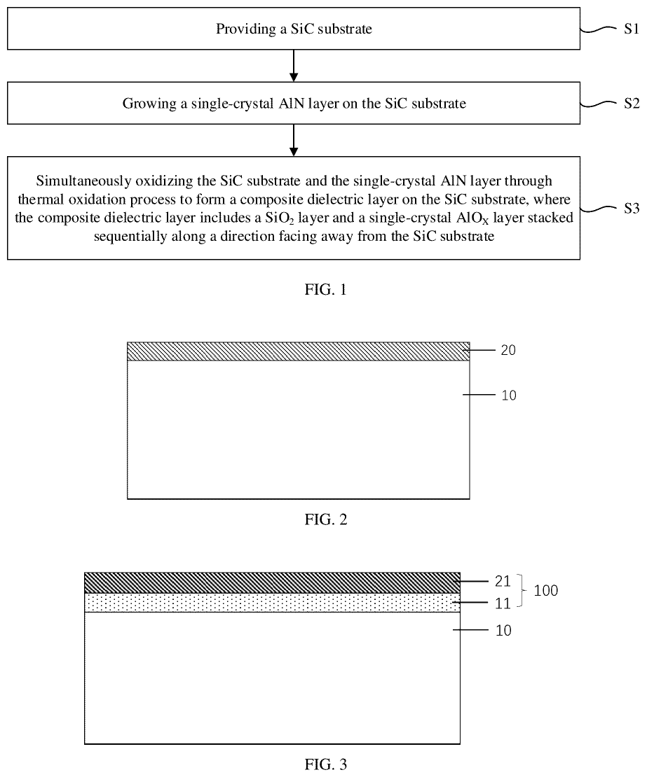

A dielectric structure, a semiconductor device structure and manufacturing methods therefor mentioned in the present disclosure will be described through embodiments with reference to FIGS. 1 to 25 in the following.

FIG. 1 is a flowchart of a manufacturing method for a dielectric structure according to an embodiment of the present disclosure; FIGS. 2 and 3 are schematic diagrams of intermediate structures corresponding to the process shown in FIG. 1.

As shown in FIGS. 2 and 3, the manufacturing method for the dielectric structure may include the following steps.

Step S1: providing a SiC substrate.

Step S2: growing a single-crystal AlN layer on the SiC substrate. As a lattice constant of the SiC substrate 10 is close to a lattice constant of the single-crystal AlN layer 20, lattice matching degree between the SiC substrate 10 and the single-crystal AlN layer 20 is good, and quality of an interface formed between AlN and SiC is high.

Step S3: simultaneously oxidizing the SiC substrate and the single-crystal AlN layer through a thermal oxidation process to form a composite dielectric layer on the SiC substrate, where the composite dielectric layer includes a SiO₂ layer and a single-crystal AlO_{X} layer stacked sequentially along a direction facing away from the SiC substrate.

Generally, due to high chemical stability (high atomic density and short chemical bond length) of SiC, thermal oxidation temperature (from 1200° C. to 1400° C.) of SiC is very high. The high thermal oxidation temperature brings defects of a process introduction type, including problems such as a deep-level trap and surface quality degradation, resulting in an interface state with a high density at the interface of SiC/SiO₂. In the present embodiment, the SiC substrate 10 and the single-crystal AlN layer 20 are simultaneously oxidized through the thermal oxidation process to form the composite dielectric layer 100 on the SiC substrate 10, and the composite dielectric layer 100 includes the SiO₂ layer 11 and the single-crystal AlO_{X} layer 21 stacked sequentially along a direction facing away from the SiC substrate 10. When the single-crystal AlN layer 20 is oxidized to form the single-crystal AlO_{X} layer 21, the single-crystal AlO_{X} layer 21 contains nitrogen ions with a concentration greater than 1E15/cm³. The nitrogen ions may diffuse into the SiO₂ layer 11, so that the SiO₂ layer 11 also contains nitrogen ions with a concentration greater than 1E15/cm³. A higher background concentration of nitrogen in the SiO₂ layer 11 may improve interface characteristics between the SiO₂ layer 11 and the SiC substrate 10, thereby reducing interface states with a high density at the interface of SiC/SiO₂ and improving quality of the SiO₂ layer 11. After oxidation of the single-crystal AlN layer 20, the single-crystal AlO_{X} layer 21 with wide band gap and high-density may be introduced. As the single-crystal AlO_{X} layer 21 has good quality and a high-quality interface with SiO₂, the quality of the composite dielectric layer 100 may be further improved. Moreover, as AlO_{X} has characteristics of wide band gap, high breakdown field strength, and high dielectric constant, as well as excellent thermal stability, it is a suitable choice for a gate dielectric material in a SiC MOS device. Compared to AlO_{X} material generated by deposition, a dielectric constant and density of AlO_{X} material generated by thermal oxidation may be further improved, thereby reducing defects and improving quality.

In the present embodiment, a thickness of the single-crystal AlN layer 20 is less than 2 μm. Accordingly, it may be avoided that the single-crystal AlN layer 20 is too thick, making it difficult for the surface of the SiC substrate 10 to be oxidized into the SiO₂ layer 11.

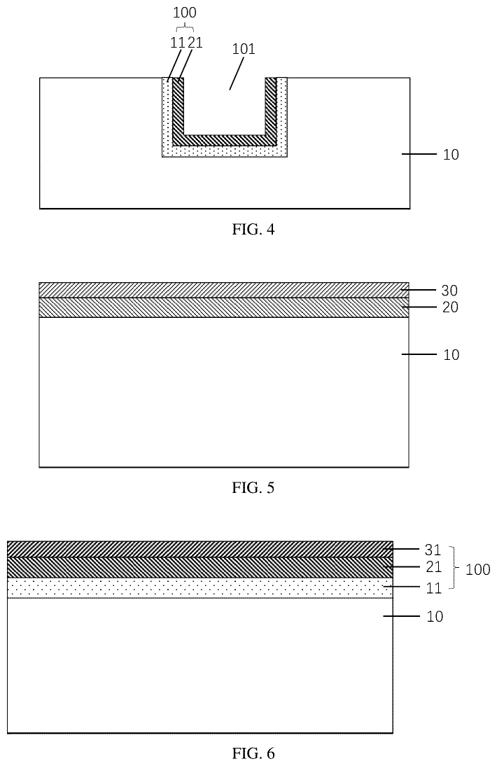

In an embodiment, FIG. 4 is a schematic structural diagram of a dielectric structure according to an embodiment of the present disclosure. FIG. 23 is a flowchart of a manufacturing method for a dielectric structure according to another embodiment of the present disclosure. As shown in FIG. 4 and FIG. 23, In step S1, the providing a SiC substrate includes the following step.

Step 11: providing a SiC substrate, where an upper surface of the SiC substrate is provided with a trench recessed inward from the upper surface.

In step S2, the growing a single-crystal AlN layer 20 on the SiC substrate 10 includes the following step.

Step S21: growing the single-crystal AlN layer on a side wall and a bottom of the trench. Then, through the thermal oxidation process, the SiO₂ layer 11 and the single-crystal AlO_{X} layer 21 are formed on the side wall and the bottom of the trench 101 of the SiC substrate 10. The dielectric structure provided in this embodiment may be used to form a trench MOS device.

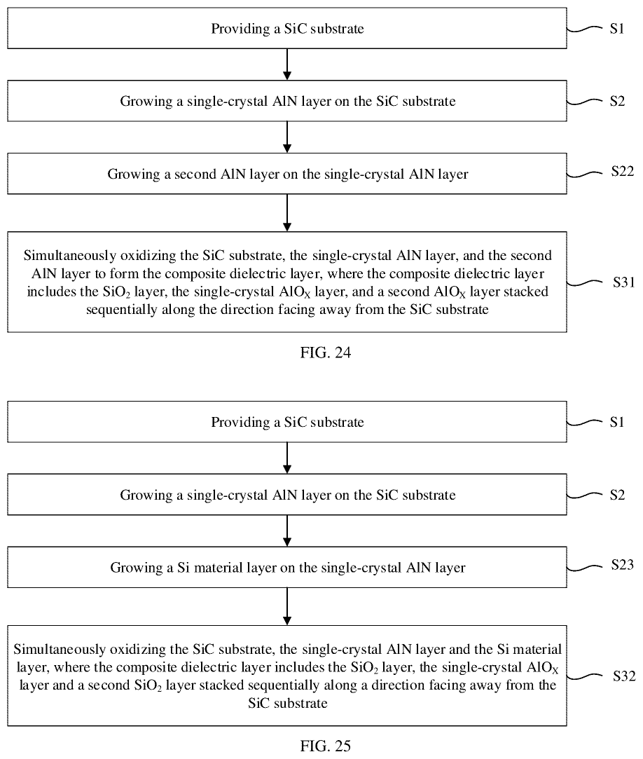

In an embodiment, FIG. 5 is a schematic structural diagram of a dielectric structure before oxidation according to an embodiment of the present disclosure, and FIG. 6 is a schematic structural diagram of a dielectric structure after oxidation according to an embodiment of the present disclosure. FIG. 24 is a flowchart of a manufacturing method for a dielectric structure according to another embodiment of the present disclosure. As shown in FIG. 24, after the step S2 of growing a single-crystal AlN layer 20 on the SiC substrate 10, the manufacturing method may further include the following step.

Step S22: growing a second AlN layer on the single-crystal AlN layer.

And the step of S3 include the following step.

Step S31: simultaneously oxidizing the SiC substrate, the single-crystal AlN layer, and the second AlN layer to form the composite dielectric layer, where the composite dielectric layer includes the SiO₂ layer, the single-crystal AlO_{X} layer, and a second AlO_{X} layer stacked sequentially along the direction facing away from the SiC substrate.

As shown in FIG. 5, the second AlN layer 30 is grown on the single-crystal AlN layer 20, and a thickness of the second AlN layer 30 is also less than 2 μm. The SiC substrate 10, the single-crystal AlN layer 20, and the second AlN layer 30 are simultaneously oxidized to form a composite dielectric layer 100 as shown in FIG. 6, including a SiO₂ layer 11, a single-crystal AlO_{X} layer 21, and a second AlO_{X} layer 31 stacked sequentially along the direction facing away from the SiC substrate 10. A material of the second AlN layer 30 includes polycrystalline AlN or amorphous AlN, and a material of the second AlO_{X} layer 31 obtained through oxidation to the second AlN layer 30 includes polycrystalline AlO_{X} or amorphous AlO_{X}. The polycrystalline or amorphous second AlO_{X} layer 31 may be used to enhance adhesion between the composite dielectric layer 100 and an upper electrode. Meanwhile, due to good ductility of polycrystalline or amorphous materials, stress caused by lattice mismatch or thermal mismatch in the dielectric structure may be alleviated by the second AlO_{X} layer 31, thereby improving the stability and lifespan of the dielectric structure.

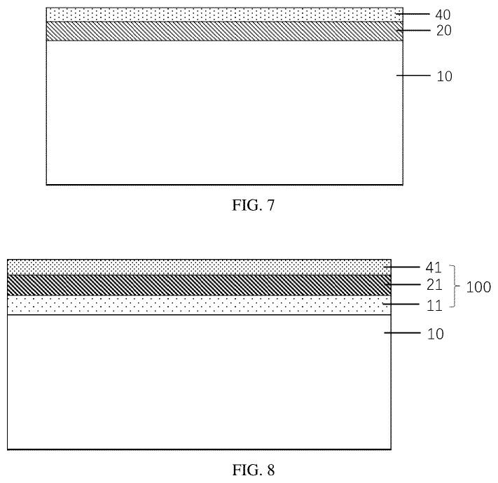

In an embodiment, FIG. 7 is a schematic structural diagram of a dielectric structure before oxidation according to an embodiment of the present disclosure, and FIG. 8 is a schematic structural diagram of a dielectric structure after oxidation according to an embodiment of the present disclosure. FIG. 25 is a flowchart of a manufacturing method for a dielectric structure according to still another embodiment of the present disclosure. After the step S2 of growing a single-crystal AlN layer 20 on the SiC substrate 10, the manufacturing method may further include the following step.

Step S23: growing a Si material layer on the single-crystal AlN layer.

And the step of S3 include the following step.

Step S32: simultaneously oxidizing the SiC substrate, the single-crystal AlN layer and the Si material layer, where the composite dielectric layer includes the SiO₂ layer, the single-crystal AlO_{X} layer and a second SiO₂ layer stacked sequentially along a direction facing away from the SiC substrate.

As shown in FIG. 7, the Si material layer 40 is grown on the single-crystal AlN layer 20. The SiC substrate 10, the single-crystal AlN layer 20, and the Si material layer 40 are simultaneously oxidized to form a composite dielectric layer 100 as shown in FIG. 8, including a SiO₂ layer 11, a single-crystal AlO_{X} layer 21, and a second SiO₂ layer 41 stacked sequentially along the direction facing away from the SiC substrate 10. The SiO₂ layer 11 and the second SiO₂ layer 41 are symmetrically arranged on both sides of the single-crystal AlO_{X} layer 21, so that stress distribution of the dielectric structure may be improved. And the thickness of the composite dielectric layer 100 is increased to reduce possibility of leakage of electricity.

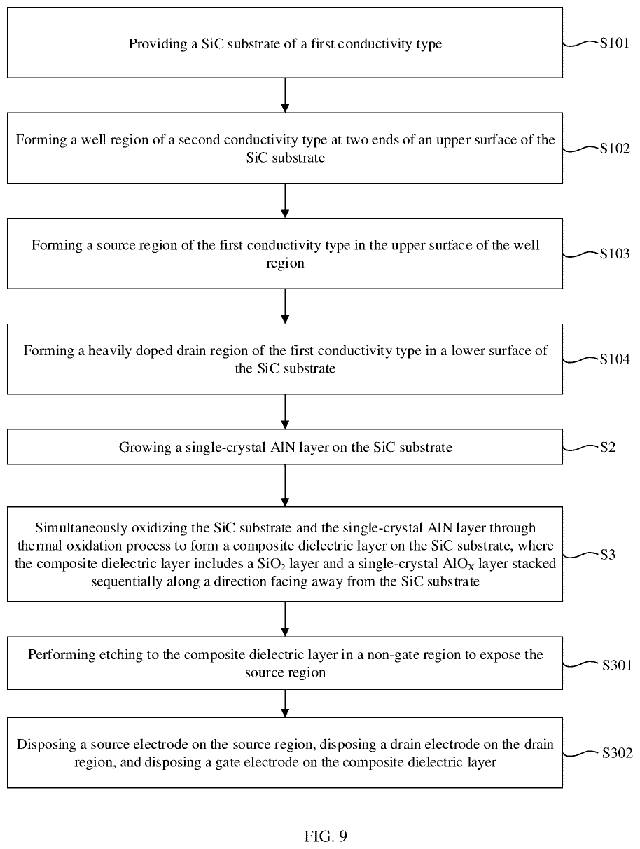

According to another aspect of the present disclosure, the present disclosure further provides a manufacturing method for a semiconductor device structure. FIG. 9 is a flowchart of a manufacturing method for a semiconductor device structure according to an embodiment of the present disclosure, and FIGS. 10 to 16 are schematic diagrams of intermediate structures corresponding to the process shown in FIG. 9. The manufacturing method for the semiconductor device structure may include the following steps.

Step S101: providing a SiC substrate of a first conductivity type.

Step S102: forming a well region of a second conductivity type at two ends of an upper surface of the SiC substrate.

Step S103: forming a source region of the first conductivity type in the upper surface of the well region.

Step S104: forming a heavily doped drain region of the first conductivity type in a lower surface of the SiC substrate.

Step S2: growing a single-crystal AlN layer on the SiC substrate.

Step S3: simultaneously oxidizing the SiC substrate and the single-crystal AlN layer through a thermal oxidation process to form a composite dielectric layer on the SiC substrate, where the composite dielectric layer includes a SiO₂ layer and a single-crystal AlO_{X} layer stacked sequentially along a direction facing away from the SiC substrate.

Step S301: performing etching to the composite dielectric layer in a non-gate region to expose the source region.

Step S302: disposing a source electrode on the source region, disposing a drain electrode on the drain region, and disposing a gate electrode on the composite dielectric layer.

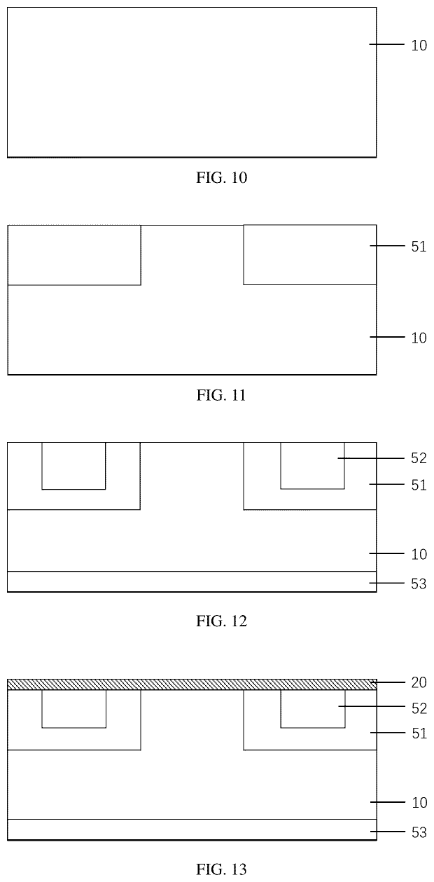

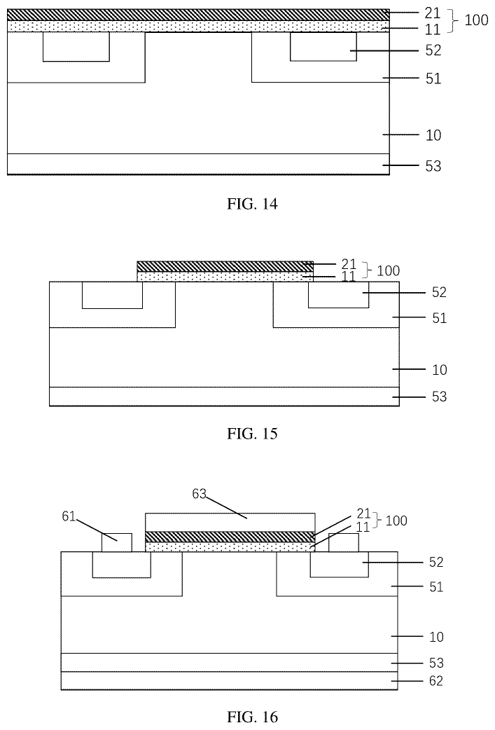

Specifically, as shown in FIG. 10, the SiC substrate 10 of the first conductivity type is provided. As shown in FIG. 11, the well region 51 of the second conductivity type are formed at two ends of the upper surface of the SiC substrate 10. As shown in FIG. 12, the source region 52 of the first conductivity type is formed in the upper surface of the well region 51 and the heavily doped drain region 53 of the first conductivity type is formed in the lower surface of the SiC substrate 10. As shown in FIG. 13, the single-crystal AlN layer 20 is grown on the SiC substrate 10, and the SiC substrate 10 and the single-crystal AlN layer 20 are simultaneously oxidized through a thermal oxidation process. As shown in FIG. 14, the composite dielectric layer 100 is formed on the SiC substrate 10, where the composite dielectric layer 100 includes the SiO₂ layer 11 and the single-crystal AlO_{X} layer 21 stacked sequentially along the direction facing away from the SiC substrate 10. As shown in FIG. 15, the composite dielectric layer 100 in a non-gate region is performed etching to expose the source region 52. The source electrode 61 is disposed on the source region 52, the drain electrode 62 is disposed on the drain region 53, and the gate electrode 63 is disposed on the composite dielectric layer 100 to form the semiconductor device structure shown in FIG. 16. The well region 51, the source region 52 and the drain region 53 are formed by means of ion implantation or secondary epitaxy after selective etching, which is not specifically limited in the present disclosure. When the semiconductor device structure prepared by the method provided in the present disclosure is used for a SiC MOS device, a leakage current of a gate dielectric layer of the SiC MOS device may be reduced, and density of an interface state at an interface of SiC/SiO₂ is reduced, thereby improving a breakdown voltage of the SiC MOS device, and further improving reliability of the SiC MOS device during high-temperature and high-power application.

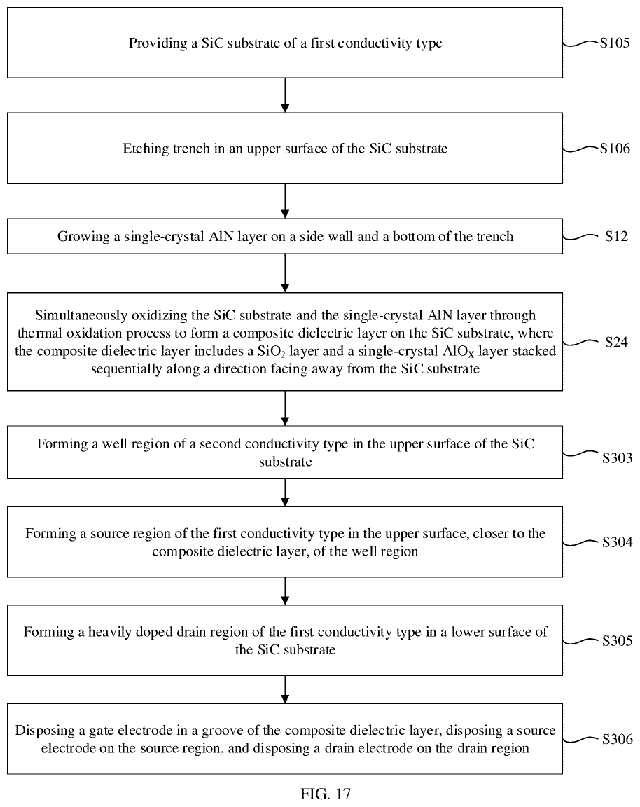

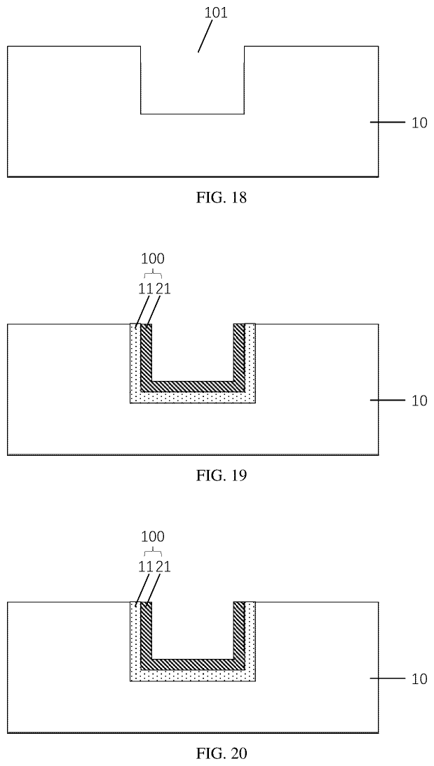

According to another aspect of the present disclosure, the present disclosure further provides a manufacturing method for a semiconductor device structure. FIG. 17 is a flowchart of a manufacturing method for a semiconductor device structure according to an embodiment of the present disclosure. FIGS. 18 to 22 are schematic diagrams of intermediate structures corresponding to the process shown in FIG. 17. The manufacturing method for the semiconductor device structure may include the following steps.

Step S105: providing a SiC substrate of a first conductivity type.

Step S106: etching a trench in an upper surface of the SiC substrate.

Step S12: growing a single-crystal AlN layer on a side wall and a bottom of the trench.

Step S24: simultaneously oxidizing the SiC substrate and the single-crystal AlN layer through a thermal oxidation process to form a composite dielectric layer on the SiC substrate, where the composite dielectric layer includes a SiO₂ layer and a single-crystal AlO_{X} layer stacked sequentially along a direction facing away from the SiC substrate.

Step S303: forming a well region of a second conductivity type in the upper surface of the SiC substrate.

Step S304: forming a source region of the first conductivity type in the upper surface, closer to the composite dielectric layer, of the well region.

Step S305: forming a heavily doped drain region of the first conductivity type in a lower surface of the SiC substrate.

Step S306: disposing a gate electrode in a groove of the composite dielectric layer, disposing a source electrode in the source region, and disposing a drain electrode in the drain region.

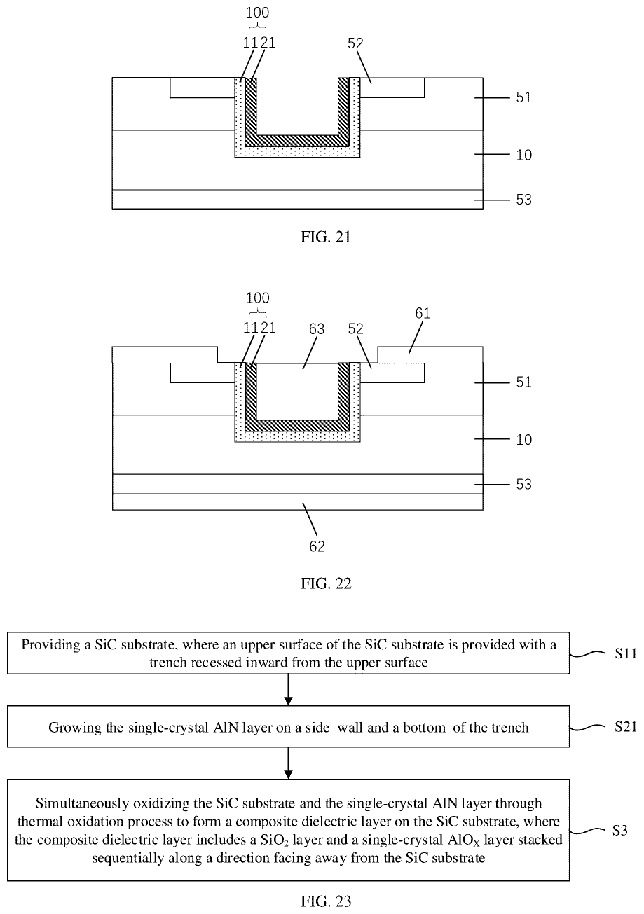

Specifically, as shown in FIG. 18, the SiC substrate 10 of the first conductivity type is provided and the trench 101 is etched in the upper surface of the SiC substrate 10. As shown in FIG. 19, the single-crystal AlN layer 20 is grown on the side wall and the bottom of the trench 101, and the SiC substrate 10 and the single-crystal AlN layer 20 are simultaneously oxidized through a thermal oxidation process. As shown in FIG. 20, the composite dielectric layer 100 is formed on the SiC substrate 10, where the composite dielectric layer 100 includes the SiO₂ layer 11 and the single-crystal AlO_{X} layer 21 stacked sequentially along a direction facing away from the SiC substrate 10. As shown in FIG. 21, the well region 51 of the second conductivity type is formed in the upper surface of the SiC substrate 10, the source region 52 of the first conductivity type is formed in the upper surface, closer to the composite dielectric layer 100, of the well region 51, and the heavily doped drain region 53 of the first conductivity type is formed in the lower surface of the SiC substrate 10. The gate electrode 63 is disposed in a groove of the composite dielectric layer 100, the source electrode 61 is disposed on the source region 52, and the drain electrode 62 is disposed on the drain region 53 to form the semiconductor device structure shown in FIG. 22.

According to another aspect of the present disclosure, the present disclosure further provides a dielectric structure, as shown in FIG. 3, the dielectric structure is a dielectric structure prepared by any one of the manufacturing methods for the dielectric structure mentioned above. The dielectric structure includes a SiC substrate 10 and a composite dielectric layer 100 stacked in layers. The composite dielectric layer 100 includes a SiO₂ layer 11 and a single-crystal AlO_{X} layer 21 stacked sequentially along a direction facing away from the SiC substrate 10.

In an embodiment, as shown in FIG. 6, the composite dielectric layer 100 may further includes a second AlO_{X} layer 31 located on a side, facing away from the SiC substrate 10, of the single-crystal AlO_{X} layer 21. A material of the second AlO_{X} layer 31 includes polycrystalline AlO_{X} or amorphous AlO_{X}. The polycrystalline or amorphous second AlO_{X} layer 31 may be used to enhance adhesion between the composite dielectric layer 100 and an upper electrode. Meanwhile, due to good ductility of polycrystalline or amorphous materials, stress caused by lattice mismatch or thermal mismatch in the dielectric structure may be alleviated by the second AlO_{X} layer 31, thereby improving the stability and lifespan of the dielectric structure.

In an embodiment, as shown in FIG. 8, the composite dielectric layer 100 may further include a second SiO₂ layer 42 located on a side, facing away from the SiC substrate 10, of the single-crystal AlO_{X} layer 21. The SiO₂ layer 11 and the second SiO₂ layer 41 are symmetrically arranged on both sides of the single-crystal AlO_{X} layer 21, so that stress distribution of the dielectric structure may be improved. And the thickness of the composite dielectric layer 100 is increased to reduce possibility of leakage of electricity.

According to another aspect of the present disclosure, the present disclosure further provides a semiconductor device structure, as shown in FIG. 16, the semiconductor device structure includes: a SiC substrate 10 of a first conductivity type; a well region 51 of a second conductivity type located at two ends of an upper surface of the SiC substrate 10; a source region 52 of the first conductivity type located in the upper surface of the well region 51 and a source electrode 61 in contact with the source region 52; a heavily doped drain region 53 of the first conductivity type located in a lower surface of the SiC substrate 10 and a drain electrode 62 in contact with the drain region 53; and a composite dielectric layer 100 and a gate electrode 63 located in the gate region of the upper surface of the SiC substrate 10, where the composite dielectric layer 100 includes a SiO₂ layer 11 and a single-crystal AlO_{X} layer 21 stacked sequentially along a direction facing away from the SiC substrate 10. When the semiconductor device structure prepared by the method provided in the present disclosure is used for a SiC MOS device, a leakage current of a gate dielectric layer of the SiC MOS device may be reduced, and density of an interface state at an interface of SiC/SiO₂ is reduced, thereby improving a breakdown voltage of the SiC MOS device, and further improving reliability of the SiC MOS device during high-temperature and high-power application.

According to another aspect of the present disclosure, the present disclosure further provides a semiconductor device structure. As shown in FIG. 22, the semiconductor device structure includes: a SiC substrate 10 of a first conductivity type, where an upper surface of the SiC substrate 10 is provided with a trench 101; a well region 51 of a second conductivity type located in the upper surface of the SiC substrate 10; a source region 52 of the first conductivity type located in the upper surface, closer to the trench 101, of the well region 51 and a source electrode 61 in contact with the source region 52; a heavily doped drain region 53 of the first conductivity type located in a lower surface of the SiC substrate 10 and a drain electrode 62 in contact with the drain region 53; and a composite dielectric layer 100 located on a side wall and a bottom of the trench 101 and a gate electrode 63 located in a groove of the composite dielectric layer 100, where the composite dielectric layer 100 includes a SiO₂ layer 11 and a single-crystal AlO_{X} layer 21 stacked sequentially along a direction facing away from the SiC substrate 10.

The present disclosure provides a dielectric structure, a semiconductor device structure, and manufacturing methods therefor. After growing a single-crystal AlN layer on a SiC substrate, the SiC substrate and the single-crystal AlN layer are simultaneously oxidized to form a composite dielectric layer including a SiO₂ layer and a single-crystal AlO_{X} layer. According to the present disclosure, by simultaneously oxidizing the single-crystal AlN layer provided on the surface of the SiC substrate and the SiC substrate, on the one hand, the AlO_{X} layer formed by the oxidation of the single-crystal AlN layer includes a higher background concentration of nitrogen, so that nitrogen ions diffuse into the SiO₂, thereby improving the interface characteristics of the SiC/SiO₂, reducing interface state with a high density at an interface of SiC/SiO₂, and improving the quality of the SiO₂ layer; on the other hand, after oxidation of the single-crystal AlN layer, the single-crystal AlO_{X} layer with wide band gap and high-density may be introduced. As the single-crystal AlO_{X} has good quality and a high-quality interface with SiO₂, quality of the composite dielectric layer may be further improved. According to the dielectric structure provided by the present disclosure, a large number of interface states existing between SiC and SiO₂ grown by a traditional direct thermal oxidation method may be reduced, thereby improving the channel mobility, and improving forward conduction capability of the device.

It should be understood that the term “including” and variations of the term “including” used in the present disclosure are open-ended, meaning “including but not limited to”. The term “an embodiment” means “at least one embodiment”. The term “another embodiment” means “at least one further embodiment”. In the specification, the schematic expressions of the above terms do not necessarily refer to the same embodiments or examples. Moreover, the specific features, structures, materials, or characteristics described can be combined in any one or more embodiments or examples in an appropriate manner. In addition, technicians in this field can combine and integrate the different embodiments or examples described in the specification, as well as the features of different embodiments or examples, without conflicting with each other.

The above is only some preferred embodiments of the present disclosure and is not intended to limit the present disclosure. Any modifications, equivalent substitutions, and the like made within the spirit and principles of the present disclosure shall fall within the scope of protection of the present disclosure.

What is claimed is:

1. A manufacturing method for a dielectric structure, comprising:
providing a SiC substrate;
growing a single-crystal AlN layer on the SiC substrate; and
simultaneously oxidizing the SiC substrate and the single-crystal AlN layer through a thermal oxidation process to form a composite dielectric layer on the SiC substrate, wherein the composite dielectric layer comprises a SiO₂ layer and a single-crystal AlO_{X} layer stacked sequentially along a direction facing away from the SiC substrate.

2. The manufacturing method according to claim 1, wherein an upper surface of the SiC substrate is provided with a trench recessed inward from the upper surface and the growing a single-crystal AlN layer on the SiC substrate comprises:
growing the single-crystal AlN layer on a side wall and a bottom of the trench.

3. The manufacturing method according to claim 1, wherein the single-crystal AlO_{X} layer comprises nitrogen ions with a concentration greater than 1E15/cm³.

4. The manufacturing method according to claim 1, wherein the SiO₂ layer comprises nitrogen ions with a concentration greater than 1E15/cm³.

5. The manufacturing method according to claim 1, wherein a thickness of the single-crystal AlN layer is less than 2 μm.

6. The manufacturing method according to claim 1, wherein after the providing a SiC substrate, and growing a single-crystal AlN layer on the SiC substrate, the manufacturing method further comprises:
growing a second AlN layer on the single-crystal AlN layer.

7. The manufacturing method according to claim 6, wherein a material of the second AlN layer comprises polycrystalline AlN or amorphous AlN.

8. The manufacturing method according to claim 6, wherein the simultaneously oxidizing the SiC substrate and the single-crystal AlN layer comprises: simultaneously oxidizing the SiC substrate, the single-crystal AlN layer and the second AlN layer, wherein the composite dielectric layer comprises the SiO₂ layer, the single-crystal AlO_{X} layer and a second AlO_{X} layer stacked sequentially along a direction facing away from the SiC substrate.

9. The manufacturing method according to claim 8, wherein a material of the second AlO_{X} layer comprises polycrystalline AlO_{X} or amorphous AlO_{X}.

10. The manufacturing method according to claim 1, wherein after the growing a single-crystal AlN layer on the SiC substrate, the manufacturing method further comprises:
growing a Si material layer on the single-crystal AlN layer.

11. The manufacturing method according to claim 10, wherein the simultaneously oxidizing the SiC substrate and the single-crystal AlN layer comprises: simultaneously oxidizing the SiC substrate, the single-crystal AlN layer and the Si material layer, wherein the composite dielectric layer comprises the SiO₂ layer, the single-crystal AlO_{X} layer and a second SiO₂ layer stacked sequentially along a direction facing away from the SiC substrate.

12. A manufacturing method for a semiconductor device structure, comprising the manufacturing method for the dielectric structure according to claim 1, wherein before the growing a single-crystal AlN layer on the SiC substrate, the providing a SiC substrate comprises:
providing a SiC substrate of a first conductivity type;
forming a well region of a second conductivity type at two ends of an upper surface of the SiC substrate;
forming a source region of the first conductivity type in the upper surface of the well region; and
forming a heavily doped drain region of the first conductivity type in a lower surface of the SiC substrate;
after the simultaneously oxidizing the SiC substrate and the single-crystal AlN layer through a thermal oxidation process to form a composite dielectric layer on the SiC substrate, wherein the composite dielectric layer comprises a SiO₂ layer and a single-crystal AlO_{X} layer stacked sequentially along a direction facing away from the SiC substrate, the method further comprises:
performing etching to the composite dielectric layer in a non-gate region to expose the source region; and
disposing a source electrode on the source region, disposing a drain electrode on the drain region, and disposing a gate electrode on the composite dielectric layer.

13. The manufacturing method for a semiconductor device structure according to claim 12, wherein the well region, the source region and the drain region are formed by means of ion implantation or secondary epitaxy after selective etching.

14. A manufacturing method for a semiconductor device structure, comprising the manufacturing method for the dielectric structure according to claim 1, wherein before the growing a single-crystal AlN layer on the SiC substrate, the providing a SiC substrate comprises:
providing a SiC substrate of a first conductivity type; and
etching a trench in an upper surface of the SiC substrate;
the growing a single-crystal AlN layer on the SiC substrate comprises: growing a single-crystal AlN layer on a side wall and a bottom of the trench; and
after the simultaneously oxidizing the SiC substrate and the single-crystal AlN layer through a thermal oxidation process to form a composite dielectric layer on the SiC substrate, wherein the composite dielectric layer comprises a SiO₂ layer and a single-crystal AlO_{X} layer stacked sequentially along a direction facing away from the SiC substrate, the method further comprises:
forming a well region of a second conductivity type in the upper surface of the SiC substrate;
forming a source region of the first conductivity type in the upper surface, closer to the composite dielectric layer, of the well region;
forming a heavily doped drain region of the first conductivity type in a lower surface of the SiC substrate; and
disposing a gate electrode in a groove of the composite dielectric layer, disposing a source electrode on the source region, and disposing a drain electrode on the drain region.

15. A dielectric structure, prepared by the manufacturing method for the dielectric structure according to claim 1, comprising a SiC substrate and a composite dielectric layer stacked in layers, wherein the composite dielectric layer comprises a SiO₂ layer and a single-crystal AlO_{X} layer stacked sequentially along a direction facing away from the SiC substrate.

16. The dielectric structure according to claim 15, wherein the composite dielectric layer further comprises a second AlO_{X} layer located on a side, facing away from the SiC substrate, of the single-crystal AlO_{X} layer.

17. The dielectric structure according to claim 16, wherein a material of the second AlO_{X} layer comprises polycrystalline AlO_{X} or amorphous AlO_{X}.

18. The dielectric structure according to claim 15, wherein the composite dielectric layer further comprises a second SiO₂ layer located on a side, facing away from the SiC substrate, of the single-crystal AlO_{X} layer.

19. A semiconductor device structure, prepared by the manufacturing method for the semiconductor device structure according to claim 12, comprising:
a SiC substrate of a first conductivity type;
a well region of a second conductivity type located at two ends of an upper surface of the SiC substrate;
a source region of the first conductivity type located in the upper surface of the well region, and a source electrode in contact with the source region;
a heavily doped drain region of the first conductivity type in a lower surface of the SiC substrate, and a drain electrode in contact with the drain region; and
a composite dielectric layer and a gate electrode located in a gate region of the upper surface of the SiC substrate, wherein the composite dielectric layer comprises a SiO₂ layer and a single-crystal AlO_{X} layer stacked sequentially along a direction facing away from the SiC substrate.

20. A semiconductor device structure, prepared by the manufacturing method for the semiconductor device structure according to claim 14, comprising:
a SiC substrate of a first conductivity type, wherein an upper surface of the SiC substrate is provided with a trench;
a well region of a second conductivity type located in the upper surface of the SiC substrate;
a source region of the first conductivity type located in the upper surface, closer to the trench, of the well region, and a source electrode in contact with the source region;
a heavily doped drain region of the first conductivity type located in a lower surface of the SiC substrate, and a drain electrode in contact with the drain region; and
a composite dielectric layer located on a side wall and a bottom of the trench, and a gate electrode located in a groove of the composite dielectric layer, wherein the composite dielectric layer comprises a SiO₂ layer and a single-crystal AlO_{X} layer stacked sequentially along a direction facing away from the SiC substrate.
